(19) United States
(12) Patent Application Publication
(10) Pub. No.: US 2026/0254420 A1
(43) Pub. Date: Aug. 27, 2026

(54) VOLTAGE RIPPLE SUPPRESSION AND MEMORY DISTORTION NEUTRALIZATION IN A WIRELESS TRANSMISSION CIRCUIT

(71) Applicant: Qorvo US, Inc., Greensboro, NC (US)

(72) Inventor: Nadim Khlat, Ceret (FR)

(21) Appl. No.: 19/471,441

(22) PCT Filed: Mar. 21, 2024
(86) PCT No.: PCT/US2024/020854

§ 371 Date: Oct. 1, 2025

Related U.S. Application Data
(60) Provisional application No. 63/456,635, filed on Apr. 3, 2023.

(51) Int. Cl. H03F 3/195; H03F 1/14; H03F 3/45

(52) U.S. Cl. CPC H03F 3/195; H03F 1/14; H03F 3/45098; H03F 2200/102; H03F 2200/451

(57) ABSTRACT

Voltage ripple suppression and memory distortion neutralization in a wireless transmission circuit are provided. The wireless transmission circuit includes a differential power amplifier circuit that amplifies a radio frequency (RF) signal based on a modulated voltage, an envelope tracking integrated circuit (ETIC) that generates the modulated voltage based on a modulated target voltage, and a transceiver circuit that generates the RF signal and the modulated target voltage. In embodiments disclosed herein, the transceiver circuit, the ETIC, and the differential power amplifier circuit are configured to collectively reduce various types of distortions (e.g., voltage ripple and memory distortion) caused by various contributing factors (e.g., trace impedance, leakage current, and/or distortion filter) in various stages of the wireless transmission circuit to thereby improve an adjacent channel leakage ratio (ACLR) of the wireless transmission circuit.

### RELATED APPLICATIONS

This application claims the benefit of U.S. provisional patent application Ser. No. 63/456,635, filed on Apr. 3, 2023, the disclosure of which is hereby incorporated herein by reference in its entirety.

### FIELD OF THE DISCLOSURE

The technology of the disclosure relates generally to voltage ripple suppression and memory distortion neutralization in a wireless transmission circuit.

### BACKGROUND

Mobile communication devices have become increasingly common in current society for providing wireless communication services. The prevalence of these mobile communication devices is driven in part by the many functions that are now enabled on such devices. Increased processing capability in such devices means that mobile communication devices have evolved from being pure communication tools into sophisticated mobile multimedia centers that enable enhanced user experiences.

The redefined user experience relies on a higher data rate offered by advanced fifth generation (5G) and 5G new radio (5G-NR) systems, in which a transmission circuit typically amplifies a radio frequency (RF) to a higher power before transmission. In a typical transmission circuit, a transceiver circuit is configured to generate the RF signal, a power management circuit is configured to generate a modulated voltage, a power amplifier circuit is configured to amplify the RF signal based on the modulated voltage, and an antenna circuit is configured to radiate the RF signal in one or more RF frequencies.

The RF signal transmitted in the 5G and 5G-NR systems is subject to stringent adjacent channel leakage ratio (ACLR) requirements imposed by standard bodies and/or regulatory authorities. The ACLR defines a ratio between a power of the RF signal transmitted on an intended radio channel and the power of the RF signal received in an unintended adjacent radio channel. Given that the ACLR of a wideband RF signal can be largely dominated by a remodulation term(s), such as a third order intermodulation product (IMD3), it is thus desirable to improve IMD3 performance of the transmission circuit to thereby improve the ACLR.

### SUMMARY

Embodiments of the disclosure relate to voltage ripple suppression and memory distortion neutralization in a wireless transmission circuit. The wireless transmission circuit includes a differential power amplifier circuit that amplifies a radio frequency (RF) signal based on a modulated voltage, an envelope tracking integrated circuit (ETIC) that generates the modulated voltage based on a modulated target voltage, and a transceiver circuit that generates the RF signal and the modulated target voltage. In embodiments disclosed herein, the transceiver circuit, the ETIC, and the differential power amplifier circuit are configured to collectively reduce various types of distortions (e.g., voltage ripple and memory distortion) caused by various contributing factors (e.g., trace impedance, leakage current, and/or distortion filter) in various stages of the wireless transmission circuit to thereby improve an adjacent channel leakage ratio (ACLR) of the wireless transmission circuit.

In one aspect, a wireless transmission circuit is provided. The wireless transmission circuit includes a differential power amplifier circuit. The differential power amplifier circuit includes an output stage. The output stage is configured to amplify an RF signal modulated in a signal modulation bandwidth based on a modulated voltage and provide the amplified RF signal to a frontend circuit. The differential power amplifier circuit also includes a neutralization circuit. The neutralization circuit is configured to inject a neutralization current into the output stage to thereby suppress a modulated leakage current caused by an inherent parasitic capacitance in the output stage. The wireless transmission circuit also includes an ETIC. The ETIC is coupled to the output stage via a conductive trace. The ETIC is configured to generate the modulated voltage in a voltage modulation bandwidth lower than the signal modulation bandwidth based on a modulated target voltage. The wireless transmission circuit also includes a transceiver circuit. The transceiver circuit is configured to generate the RF signal in the signal modulation bandwidth. The transceiver circuit is also configured to generate the modulated target voltage configured to compensate for a total inductive impedance collectively presented to the output stage by the ETIC and the conductive trace and a voltage distortion filter presented to the output stage by the frontend circuit.

In another aspect, a method for suppressing voltage ripple and neutralizing memory distortion in a wireless transmission circuit is provided. The method includes amplifying, in an output stage of a differential power amplifier circuit, an RF signal modulated in a signal modulation bandwidth based on a modulated voltage and providing the amplified RF signal to a frontend circuit. The method also includes injecting a neutralization current into the output stage to thereby suppress a modulated leakage current caused by an inherent parasitic capacitance in the output stage. The method also includes generating, in an ETIC, the modulated voltage in a voltage modulation bandwidth lower than the signal modulation bandwidth based on a modulated target voltage and providing the modulated voltage to the output stage via a conductive trace. The method also includes generating, in a transceiver circuit, the modulated target voltage to compensate for a total inductive impedance collectively presented to the output stage by the ETIC and the conductive trace and a voltage distortion filter presented to the output stage by the frontend circuit.

In another aspect, a wireless device is provided. The wireless device includes a frontend circuit. The wireless device also includes a wireless transmission circuit. The wireless transmission circuit includes a differential power amplifier circuit. The differential power amplifier circuit includes an output stage. The output stage is configured to amplify an RF signal modulated in a signal modulation bandwidth based on a modulated voltage and provide the amplified RF signal to the frontend circuit. The differential power amplifier circuit also includes a neutralization circuit. The neutralization circuit is configured to inject a neutralization current into the output stage to thereby suppress a modulated leakage current caused by an inherent parasitic capacitance in the output stage. The wireless transmission circuit also includes an ETIC. The ETIC is coupled to the output stage via a conductive trace. The ETIC is configured to generate the modulated voltage in a voltage modulation bandwidth lower than the signal modulation bandwidth based on a modulated target voltage. The wireless transmission circuit also includes a transceiver circuit. The transceiver circuit is configured to generate the RF signal in the signal modulation bandwidth. The transceiver circuit is also configured to generate the modulated target voltage configured to compensate for a total inductive impedance collectively presented to the output stage by the ETIC and the conductive trace and a voltage distortion filter presented to the output stage by the frontend circuit.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an existing wireless transmission circuit that can suffer a degraded adjacent channel leakage ratio (ACLR) performance due to memory distortion caused by a power amplifier circuit in a radio frequency (RF) signal;

FIG. 1B is a schematic diagram illustrating an inner structure of an output-stage in the power amplifier circuit in FIG. 1A;

FIG. 2 is a schematic diagram of an exemplary differential power amplifier circuit wherein a neutralization circuit is configured according to an embodiment of the present disclosure to neutralize a memory distortion;

FIG. 3 is a schematic diagram providing an exemplary illustration of the neutralization circuit in the differential power amplifier circuit of FIG. 2;

FIG. 4 is a schematic diagram of an exemplary wireless transmission circuit incorporating the differential power amplifier circuit of FIG. 2;

FIG. 5 is a schematic diagram providing an exemplary illustration of a transceiver circuit in the wireless transmission circuit of FIG. 4;

FIGS. 6A and 6B are graphic diagrams providing exemplary illustrations of a window-based bandwidth adaptation scheme performed by the transceiver circuit of FIG. 5;

FIG. 7 is a schematic diagram of an exemplary communication device wherein the wireless transmission circuit of FIG. 4 can be provided; and

FIG. 8 is a flowchart of an exemplary process for suppressing voltage ripple and neutralizing memory distortion in the wireless transmission circuit of FIG. 4.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to voltage ripple suppression and memory distortion neutralization in a wireless transmission circuit. The wireless transmission circuit includes a differential power amplifier circuit that amplifies a radio frequency (RF) signal based on a modulated voltage, an envelope tracking integrated circuit (ETIC) that generates the modulated voltage based on a modulated target voltage, and a transceiver circuit that generates the RF signal and the modulated target voltage. In embodiments disclosed herein, the transceiver circuit, the ETIC, and the differential power amplifier circuit are configured to collectively reduce various types of distortions (e.g., voltage ripple and memory distortion) caused by various contributing factors (e.g., trace impedance, leakage current, and/or distortion filter) in various stages of the wireless transmission circuit to thereby improve an adjacent channel leakage ratio (ACLR) of the wireless transmission circuit.

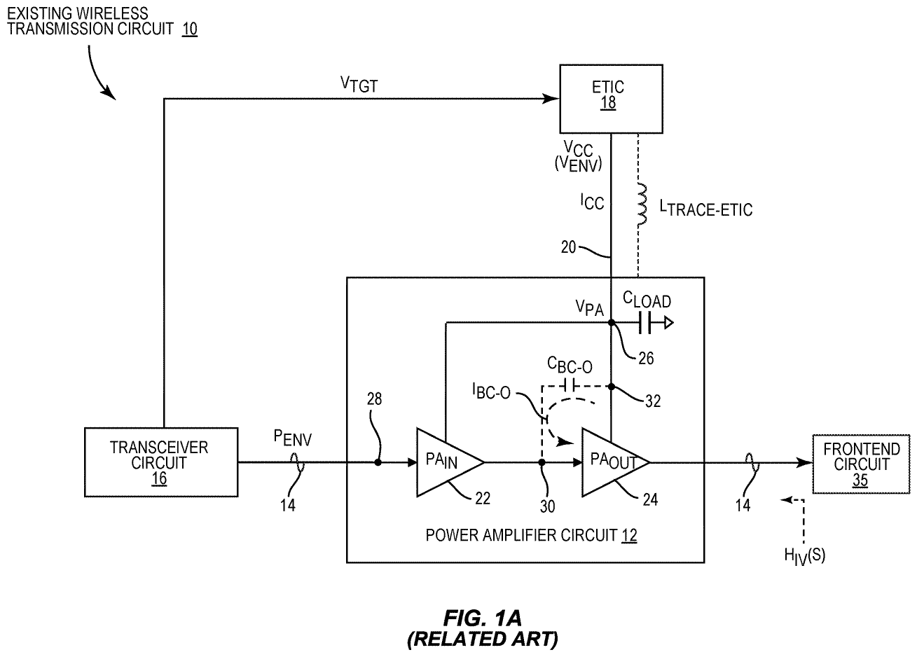

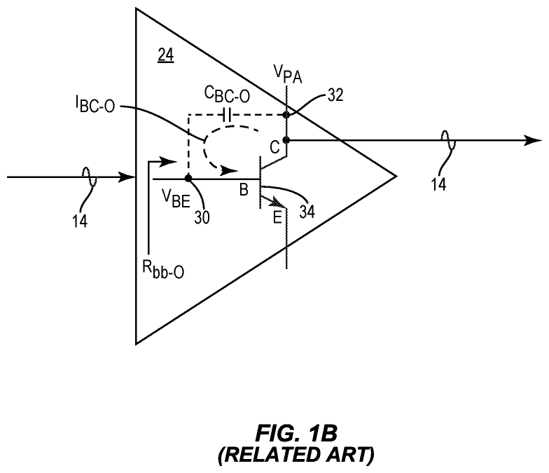

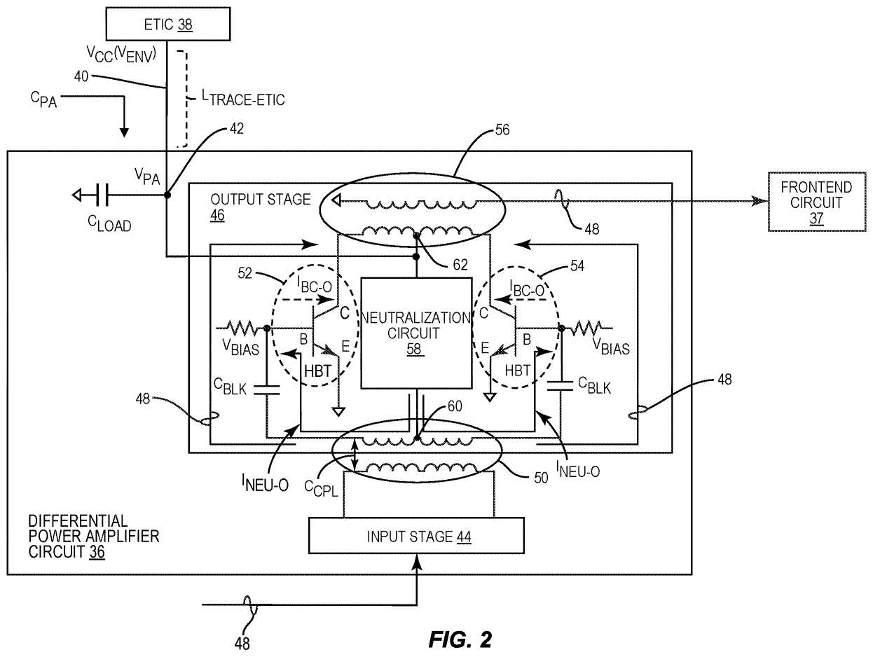

Before discussing a power amplifier circuit and a wireless communication circuit according to the present disclosure, starting at FIG. 2, a brief discussion of an existing wireless transmission circuit is first provided with reference to FIGS. 1A and 1B to help understand how a memory distortion may be created at a collector node(s) of a power amplifier circuit.

FIG. 1A is a schematic diagram of an exemplary existing wireless transmission circuit 10 that can suffer degraded ACLR performance due to memory distortion caused by a power amplifier circuit 12 in an RF signal 14. The existing wireless transmission circuit 10 includes a transceiver circuit 16 and an ETIC 18. The transceiver circuit 16 is configured to generate and provide the RF signal 14 to the power amplifier circuit 12. The transceiver circuit 16 is also configured to generate a target voltage V_{TGT} according to a power envelope P_{ENV} of the RF signal 14 and provide the target voltage V_{TGT} to the ETIC 18. The ETIC 18 is configured to generate a modulated voltage V_{CC} based on the target voltage V_{TGT}. Notably, since the modulated voltage V_{CC} is generated based on the target voltage V_{TGT} and the target voltage V_{TGT} is generated according to the power envelope P_{ENV} of the RF signal 14, the modulated voltage V_{CC} is thus associated with a voltage envelope V_{ENV} that tracks the power envelope P_{ENV} of the RF signal 14. The ETIC 18 is configured to provide the modulated voltage V_{CC} to the power amplifier circuit 12 via a conductive trace 20, which is associated with a respective equivalent inductive impedance L_{TRACE-ETIC}. Notably, the total inductive impedance L_{TRACE-ETIC} may be influenced by an inherent inductive impedance of the ETIC 18 and an inherent inductive impedance of the conductive trace 20.

Herein, the power amplifier circuit 12 is a multi-stage power amplifier that includes an input-stage 22 (denoted as “PAIN”) and an output-stage 24 (denoted as “PA_{OUT}”). The input-stage 22 and the output-stage 24 are configured to receive the modulated voltage V_{CC} at a common collector node 26. For the convenience of distinction, the modulated voltage V_{CC} as received at the common collector node 26 is herein after referred to as the “received modulated voltage V_{PA}.” Notably, the equivalent inductive impedance L_{TRACE-ETIC} associated with the conductive trace 20 can interact with a load current I_{CC} to create a ripple in the modulated voltage V_{CC}. As a result, the received modulated voltage V_{PA} may be different from the modulated voltage V_{CC} in phase and/or amplitude. In this regard, the ripple caused by the equivalent inductive impedance L_{TRACE-ETIC} associated in the modulated voltage V_{CC} is a first type of unwanted distortion that needs to be removed from the existing wireless transmission circuit 10.

The input-stage 22 is configured to receive the RF signal 14 via an input-stage input node 28 and amplify the RF signal 14 based on the received modulated voltage V_{PA}. The output-stage 24 is configured to receive the RF signal 14, as already amplified by the input-stage 22, via an output-stage input node 30. Accordingly, the output-stage 24 will further amplify the RF signal 14 based on the received modulated voltage V_{PA}.

The output-stage 24 has a respective parasitic collector-base capacitance between an output-stage collector node 32 and the output-stage input node 30, as denoted by a respective equivalent capacitor C_{BC-O}. As discussed in detail in FIG. 1B, the equivalent capacitor C_{BC-O} is the main contributor to the memory distortion in the power amplifier circuit 12.

FIG. 1B is a schematic diagram illustrating an inner structure of the output-stage 24 in the power amplifier circuit 12 in FIG. 1A. Common elements between FIGS. 1A and 1B are shown therein with common element numbers and will not be re-described herein.

The output-stage 24 can include a transistor 34, such as a bipolar junction transistor (BJT) or a complementary metal-oxide semiconductor (CMOS) transistor. Taking the BJT as an example, the transistor 34 can include a base electrode B, a collector electrode C, and an emitter electrode E. The collector electrode C is coupled to the output-stage collector node 32 to receive the modulated voltage V_{PA}.

The received modulated voltage V_{PA} can include both linear terms and non-linear terms, as expressed in equation (Eq. 1) below.

$${V}_{PA} = {V}_{DC} + A \times {V}_{ENV} + B \times {V}_{{ENV}^{2}} + C \times {V}_{{ENV}^{3}} + … \qquad ( Eq . 1 )$$

In the equation (Eq. 1), V_{DC} represents a constant direct-current (DC) voltage, A×V_{ENV} represents the linear term, and B×V_{ENV}²+C×V_{ENV}³+ . . . represents the non-linear term. Studies have shown that the received modulated voltage V_{PA} is dominated by the linear term A×V_{ENV}. As such, the received modulated voltage V_{PA} can be linearly approximated by equation (Eq. 2).

$${V}_{PA} \approx {V}_{DC} + A \times {V}_{ENV} \qquad ( Eq . 2 )$$

When the received modulated voltage V_{PA} is applied across the equivalent capacitor C_{BC-O} between the output-stage collector node 32 and the output-stage input node 30, a modulated output-stage current I_{BC-O} is injected from the output-stage collector node 32 into the output-stage input node 30. In this regard, the modulated output-stage current I_{BC-O} is also referred to as a “modulated leakage current” hereinafter. As shown in equation (Eq. 3) below, the modulated output-stage current I_{BC-O} is largely a linearly modulated current.

$${I}_{CB - O} \approx {C}_{BC - O} \times A \times {dV}_{ENV} / dt \qquad ( Eq . 3 )$$

The modulated output-stage current I_{BC-O} is converted by an output-stage net impedance R_{bb-O} presenting at the base electrode B of the output-stage 24 into a voltage R_{bb-O}×I_{CB-O}, which is then added to the RF signal 14 at the base electrode B of the transistor 34 to create a distorted base voltage V_{BE}, as shown in equation (Eq. 4) below.

$${V}_{BE} \approx {V}_{ENV} \times {K}_{RF} \times sin ( ω ct + φ ( t ) ) + {R}_{bb - O} \times {I}_{CB - O} \qquad ( Eq . 4 )$$

In the equation (Eq. 4), K_{RF} represents a dimensionless constant (e.g., a constant gain). The voltage envelope V_{ENV} and the RF signal 14 re-modulate through even order (primarily 2^{nd} order) distortion within the output-stage 24 to generate an output-stage distortion product that can be expressed as:

$${K}_{O} \times {R}_{bb - O} \times {I}_{CB - O} \times {V}_{ENV} \times {K}_{RF} \times sin ( ωct + φ ( t ) )$$

Notably, as a derivative of the voltage envelope V_{ENV}, the output-stage distortion product inherently has a memory (a.k.a. memory effect), which can be difficult to compensate for by such techniques as isoGain and linear digital predistortion (DPD). As a result, the power amplifier circuit 12 can suffer a degraded ACLR performance. In this regard, the output-stage distortion product is a second type of unwanted distortion that needs to be removed from the existing wireless transmission circuit 10.

With reference back to FIG. 1A, the power amplifier circuit 12 is typically coupled to a frontend circuit(s) 35 (e.g., RF filter, antenna switch, etc.), which presents an unwanted voltage distortion filter H_{IV}(s) to the output-stage 24 of the power amplifier circuit 12. For an in-depth discussion of the cause and impact of the unwanted voltage distortion filter H_{IV}(s), please refer to U.S. Patent Application Publication Number 2022/0407463 A1, entitled “WIDEBAND TRANSMISSION CIRCUIT.” Accordingly, the unwanted voltage distortion filter H_{IV}(s) is a third type of unwanted distortion that needs to be removed from the existing wireless transmission circuit 10.

Thus, the technical problem to be solved herein is to remove all three types of unwanted distortions from the existing wireless transmission circuit 10. Moreover, it is desirable to remove all three types of unwanted distortions when a modulation bandwidth of the RF signal 14 exceeds a bandwidth limitation of the ETIC 18.

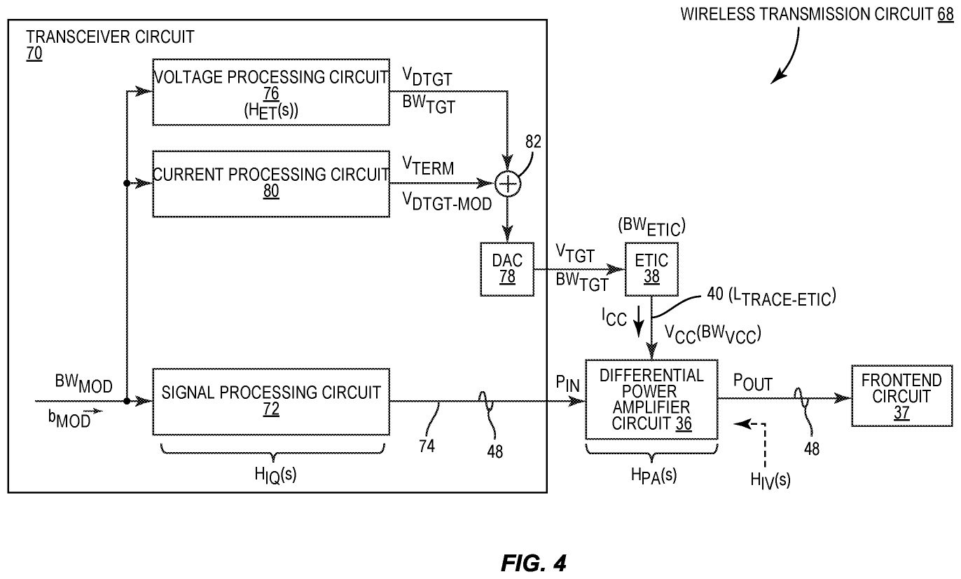

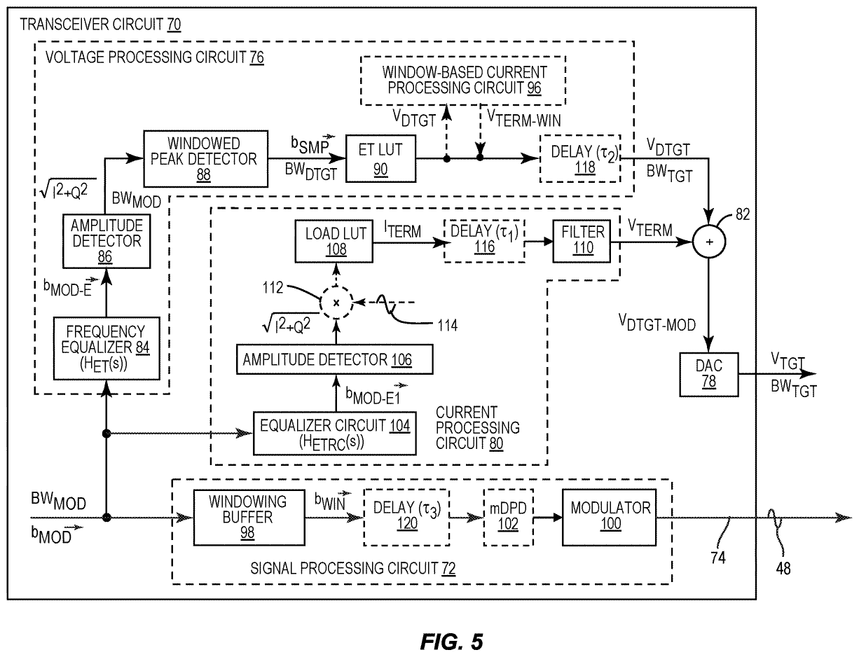

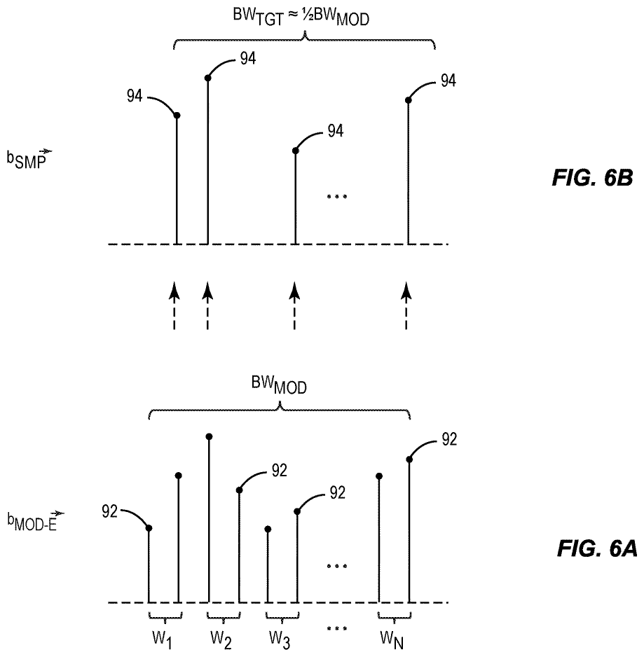

In embodiments disclosed herein, a wireless transmission circuit can be configured to effectively remove or suppress all three types of unwanted distortions to thereby achieve a much-improved ACLR performance. Specifically, FIG. 2 describes a differential power amplifier circuit configured to reduce the second type of unwanted distortion in the existing wireless transmission circuit 10, FIGS. 4 and 5 are directed to removing the first and third types of unwanted distortions in the existing wireless transmission circuit 10, and FIGS. 6A and 6B illustrate how to resolve the bandwidth mismatch issue in the existing wireless transmission circuit 10.

In this regard, FIG. 2 is a schematic diagram of an exemplary differential power amplifier circuit 36 configured according to an embodiment of the present disclosure to neutralize the output-stage distortion presenting in the existing wireless transmission circuit 10 of FIG. 1A. In an embodiment, the differential power amplifier circuit 36 can replace the power amplifier circuit 12 in FIG. 1A and be coupled to a frontend circuit 37 (e.g., RF filter, antenna switch, etc.). The differential power amplifier circuit 36 is also coupled to an ETIC 38 via a conductive trace 40. As such, the ETIC 38 and the conductive trace 40 can collectively present a total inductive impedance L_{TRACE-ETIC} to the differential power amplifier circuit 36.

The ETIC 38 is functionally equivalent to the ETIC 18 in FIG. 1A. In this regard, the ETIC 38 is configured to generate a modulated voltage V_{CC} associated with a voltage envelope V_{ENV} and provide the modulated voltage V_{CC} to a common collector node 42 in the differential power amplifier circuit 36 via the conductive trace 40. Typically, the common collector node 42 is coupled to a decoupling capacitor C_{LOAD}, which defines a portion of the equivalent capacitance C_{PA} of the differential power amplifier circuit 36.

Given the influence of the total inductive impedance L_{TRACE-ETIC}, the modulated voltage V_{CC} as received at the common collector node 42 may be modified (e.g., in amplitude and/or phase) from the modulated voltage V_{CC} generated by the ETIC 38. For the purpose of distinction, the modulated voltage V_{CC} as received at the common collector node 42 is hereinafter referred to as the “received modulated voltage V_{PA}.”

The differential power amplifier circuit 36 includes an input stage 44 and an output stage 46. The input stage 44 is configured to amplify an RF signal 48. The output stage 46 is coupled to the input stage 44 via an interstage transformer 50 and configured to receive the amplified RF signal 48 from the input stage 44 via the interstage transformer 50.

The output stage 46 includes a pair of differential amplifiers 52, 54, each coupled to the interstage transformer 50 via a respective blocking capacitor C_{BLK}. The differential amplifiers 52, 54 are each configured to further amplify the RF signal 48, which has already been amplified by the input stage 44, based on the received modulated voltage V_{PA}. The differential amplifiers 52, 54 are each coupled to an output transformer 56 that outputs the RF signal 48 after being further amplified by the differential amplifiers 52, 54.

In a non-limiting example, each of the differential amplifiers 52, 54 includes a respective heterojunction bipolar transistor (HBT). Specifically, the HBT transistor includes a base electrode (denoted as “B”) coupled to the blocking capacitor C_{BLK} and receives a bias voltage VBIAS, a collector electrode (denoted as “C”) coupled to the output transformer 56, and an emitter electrode (denoted as “E”) coupled to ground.

The transistor HBT in each of the differential amplifiers 52, 54 can be identical to the transistor 34 illustrated in FIG. 1B. In this regard, like the transistor 34 in FIG. 1B, the transistor HBT in each of the differential amplifiers 52, 54 also has the equivalent capacitor C_{BC-O} (not shown herein for the sake of simplicity) between the collector electrode C and the base electrode B. As such, when the received modulated voltage V_{PA} is applied across the equivalent capacitor C_{BC-O}, a modulated output-stage current I_{BC-O}, as expressed in the equation (Eq. 3) above, is injected from the collector electrode C into the base collector B through the equivalent capacitor C_{BC-O}. Understandably from previous discussions, the modulated output-stage current I_{BC-O} can cause the voltage envelope V_{ENV} and the RF signal 48 to re-modulate through even order (primarily 2^{nd} order) distortion within the output stage 46 to generate an output-stage distortion product that can degrade the ACLR of the differential power amplifier circuit 36.

In this regard, the output stage 46 is configured to include a neutralization circuit 58. The neutralization circuit 58 is configured to generate an output-stage neutralization current I_{NEU-O} and inject the output-stage neutralization current I_{NEU-O} into the base electrode B of the transistor HBT in each of the differential amplifiers 52, 54. Specifically, the output-stage neutralization current I_{NEU-O} is so generated to be approximately equal (e.g., I_{NEU-O}=I_{BC-O}±1%) to the modulated output-stage current I_{BC-O} but flows in an opposite direction from the modulated output-stage current I_{BC-O}. According to embodiments described herein, the neutralization circuit 58 is configured to generate the output-stage neutralization current I_{NEU-O} at a baseband frequency (e.g., <200 MHz), which is substantially lower than a carrier frequency (e.g., >2 GHz) of the RF signal 48. By neutralizing the modulated output-stage current I_{BC-O} in the output stage 46, it is possible to prevent the unwanted memory distortion from being generated, thus helping to improve the ACLR of the differential power amplifier circuit 36.

According to an embodiment of the present disclosure, the neutralization circuit 58 is coupled between a center tap 60 of the interstage transformer 50 and a center tap 62 of the output transformer 56. The neutralization circuit 58 is configured to receive the modulated voltage V_{PA} via the center tap 62 of the output transformer 56 and derive the output-stage neutralization current I_{NEU-O} from the received modulated voltage V_{PA}. Accordingly, the neutralization circuit 58 injects the output-stage neutralization current I_{NEU-O} into the base electrode B of the transistor HBT in each of the differential amplifiers 52, 54 via the center tap 60 of the interstage transformer 50.

Notably, the center tap 60 and the center tap 62 are virtual earth (a.k.a. virtual ground) points. Herein, a virtual earth point is a node in an electrical circuit that is maintained at a steady reference potential, without being connected directly to any reference potential. As such, the neutralization circuit 58 can be turned on and off without impacting amplitude-amplitude (AM/AM) and amplitude-phase (AM/PM) waterfall curves of the RF signal 48. Moreover, it is possible to retrofit the neutralization circuit 58 into an existing differential power amplifier circuit.

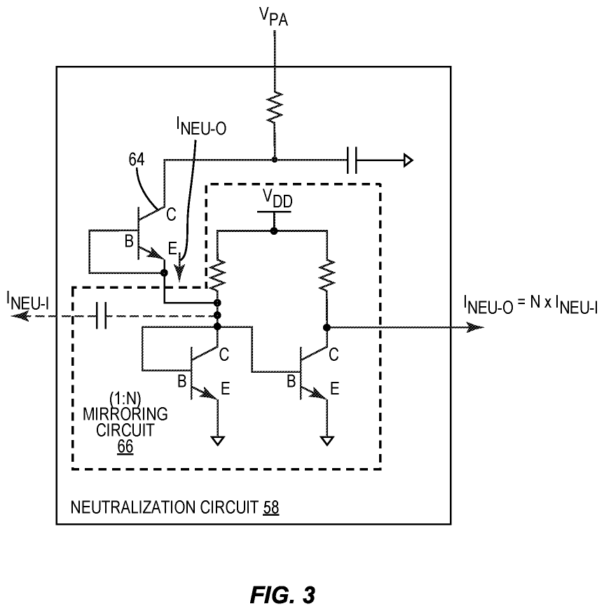

FIG. 3 is a schematic diagram providing an exemplary illustration of the neutralization circuit 58 in FIG. 2 configured according to an embodiment of the present disclosure. Common elements between FIGS. 2 and 3 are shown therein with common element numbers and will not be re-described herein.

In one embodiment, the neutralization circuit 58 can be configured to include an HBT 64 and a mirroring circuit 66. The HBT 64 is configured to derive the output-stage neutralization current I_{NEU-O} from the received modulated voltage V_{PA}. In an alternative embodiment, the HBT 64 may also be replaced by a capacitor. The mirroring circuit 66 (e.g., 1-to-N mirroring circuit) is configured to amplify the output-stage neutralization current I_{NEU-O} (e.g., by N times), invert a direction of the output-stage neutralization current I_{NEU-O}, and inject the amplified output-stage neutralization current I_{NEU-O} into the center tap 60 of the interstage transformer 50.

The differential power amplifier circuit 36 of FIG. 2 can be provided in a wireless communication circuit (e.g., a wireless device) to neutralize the unwanted memory distortion while amplifying the RF signal 48 based on the modulated voltage V_{CC}. In this regard, FIG. 4 is a schematic diagram of an exemplary wireless transmission circuit 68 incorporating the differential power amplifier circuit 36 of FIG. 2. Common elements between FIGS. 2 and 4 are shown therein with common element numbers and will not be re-described herein.

The wireless transmission circuit 68 further includes a transceiver circuit 70, which is coupled to the ETIC 38 and the differential power amplifier circuit 36. The transceiver circuit 70 includes a signal processing circuit 72. The signal processing circuit 72 receives a time-variant modulation vector b_{MOD}^{→} (e.g., from a baseband processor) modulated in a signal modulation bandwidth BW_{MOD} and generates the RF signal 48 from the time-variant modulation vector b_{MOD}^{→}. Given that the RF signal 48 is generated from the time-variant modulation vector b_{MOD}^{→}, the modulation bandwidth of the RF signal 48 is substantially identical to the signal modulation bandwidth BW_{MOD} of the time-variant modulation vector b_{MOD}^{→}. The signal processing circuit 72 is further configured to provide the RF signal 48 to the differential power amplifier circuit 36 via a conductive signal path 74.

The transceiver circuit 70 also includes a voltage processing circuit 76. The voltage processing circuit 76 receives the time-variant modulation vector b_{MOD}^{→} and generates a modulated digital target voltage V_{DTGT} based on the time-variant modulation vector b_{MOD}^{→}. The transceiver circuit 70 further includes a digital-to-analog converter (DAC) 78. The DAC 78 is configured to convert the modulated digital target voltage V_{DTGT} to the modulated target voltage V_{TGT} and provide the modulated target voltage V_{TGT} to the ETIC 38.

The ETIC 38, which may be functionally equivalent to the ETIC 18 in FIG. 1A, is configured to generate the modulated voltage V_{CC} based on the modulated target voltage V_{TGT} and provide the modulated voltage V_{CC} to the differential power amplifier circuit 36 via the conductive trace 40. As mentioned earlier, the ETIC 38 and the conductive trace 40 can collectively present the total inductive impedance L_{TRACE-ETIC} to the differential power amplifier circuit 36. Notably, the total inductive impedance L_{TRACE-ETIC} may be influenced by an inherent inductive impedance of the ETIC 38 and an inherent inductive impedance of the conductive trace 40.

The differential power amplifier circuit 36 is configured to amplify the RF signal 48 from a time-variant input power P_{IN} to a time-variant output power POUT based on the modulated voltage V_{CC} and a modulated current I_{CC}, which is generated inside the differential power amplifier circuit 36 as a function of the time-variant input power P_{IN}.

In a non-limiting example, the signal modulation bandwidth BW_{MOD} of the RF signal 48 can be as wide as 400 MHz. In contrast, the ETIC 38 may have a limited bandwidth BW_{ETIC} that is significantly lower than the signal modulation bandwidth BW_{MOD} (BW_{ETIC}<BW_{MOD}). In this regard, if the transceiver circuit 70 always generates the modulated target voltage V_{TGT} with the target voltage bandwidth BW_{TGT} that is substantially identical to the signal modulation bandwidth BW_{MOD}, the ETIC 38 may be forced to chop off a portion of the target voltage bandwidth BW_{TGT}, thus causing a distortion in the modulated voltage V_{CC}. Consequently, when the differential power amplifier circuit 36 amplifies the RF signal 48 based on the distorted modulated voltage V_{CC}, the amplified RF signal 48 may be distorted as well.

In this regard, the voltage processing circuit 76 is configured to reduce the target voltage bandwidth BW_{TGT} in accordance with the limited bandwidth BW_{ETIC} of the ETIC 38. In other words, the target voltage bandwidth BW_{TGT} is equal to the limited bandwidth BW_{ETIC} (BW_{TGT}=BW_{ETIC}) but lower than the signal modulation bandwidth BW_{MOD} (BW_{TGT}<BW_{MOD}). Understandably, since the ETIC 38 generates the modulated voltage V_{CC} based on the modulated target voltage V_{TGT}, the modulated voltage V_{CC} will be associated with a voltage modulation bandwidth BW_{VCC} that is lower than the signal modulation bandwidth BW_{MOD} as well (BW_{VCC}<BW_{MOD}). Hence, in context of the present disclosure, the differential power amplifier circuit 36 is configured to amplify the RF signal 48 based on the modulated voltage V_{CC} that is associated with the voltage modulation bandwidth BW_{VCC} lower than the signal modulation bandwidth of the RF signal 48.

Notably, the modulated current I_{CC} can also interact with the total inductive impedance L_{TRACE-ETIC} to cause a ripple in the modulated voltage V_{CC}. In addition, the ripple in the modulated voltage V_{CC} can become worse when the modulated voltage V_{CC} is generated based on the reduced target voltage bandwidth BW_{TGT}. Further, as the differential power amplifier circuit 36 is also coupled to an RF front-end circuit (not shown), an unwanted voltage distortion filter H_{IV}(s) will be present at the differential power amplifier circuit 36. In this regard, it is also necessary to cancel the ripple in the modulated voltage V_{CC} and suppress the unwanted voltage distortion filter H_{IV}(s) to help improve an overall RF performance of the wireless transmission circuit 68.

In this regard, in an embodiment, the voltage processing circuit 76 is further configured to apply a complex voltage filter H_{ET}(s) to the time-variant modulation vector b_{MOD}^{→} and generate the modulated digital target voltage V_{DTGT} thereafter. The complex voltage filter H_{ET}(s), which can be expressed in equation (Eq. 5) below, is determined to compensate for the voltage distortion filter H_{IV}(s) presented to the differential power amplifier circuit 36.

$${H}_{ET} ( s ) = {H}_{IQ} ( s ) * {H}_{PA} ( s ) * {H}_{IV} ( s ) \qquad ( Eq . 5 )$$

In the equation (Eq. 5), H_{IQ}(s) represents a transfer function of the signal processing circuit 72, and H_{PA}(S) represents a voltage gain transfer function of the differential power amplifier circuit 36. In this regard, H_{ET}(s) is a combined complex filter configured to match a combined filter that includes the transfer function H_{IQ}(s), the voltage gain transfer function H_{PA}(s), and the voltage distortion filter H_{IV}(s).

To cancel the ripple in the modulated voltage V_{CC}, the transceiver circuit 70 is further configured to include a current processing circuit 80. The current processing circuit 80 is configured to determine a compensation term V_{TERM} based on the modulated voltage V_{CC} and the total inductive impedance L_{TRACE-ETIC}. In a non-limiting example, the compensation term V_{TERM} is associated with a full modulation bandwidth of the wireless transmission circuit 68 to thereby cancel the ripple across the wide modulation bandwidth BW_{MOD} of the RF signal 48.

The transceiver circuit 70 can further include a combiner 82 to combine the compensation term V_{TERM} with the modulated digital target voltage V_{DTGT} to create a modified digital target voltage V_{DTGT-MOD}. Accordingly, the DAC 78 can convert the modified digital target voltage V_{DTGT-MOD} (instead of the modulated digital target voltage V_{DTGT}) into the modulated target voltage V_{TGT}. By adding the compensation term V_{TERM} into the modulated target voltage V_{TGT}, it is possible to cancel the ripple in the modulated voltage V_{CC} received by the differential power amplifier circuit 36.

FIG. 5 is a schematic diagram providing an exemplary illustration of the transceiver circuit 70 in FIG. 4 configured according to one embodiment of the present disclosure. Common elements between FIGS. 4 and 5 are shown therein with common element numbers and will not be re-described herein.

Herein, the voltage processing circuit 76 includes a frequency equalizer circuit 84, an amplitude detector 86, a windowed peak detector circuit 88, and an ET lookup table (LUT) circuit 90. The frequency equalizer circuit 84 is configured to apply the complex voltage filter H_{ET}(s) to the time-variant modulation vector b_{MOD} to generate a frequency-equalized modulation vector b_{MOD-E}^{→}, which is also associated with the signal modulation bandwidth BW_{MOD}. The amplitude detector 86 is configured to detect a time-variant amplitude \sqrt{I²+Q²} from the frequency-equalized modulation vector b_{MOD-E}^{→} that is also associated with the signal modulation bandwidth BW_{MOD}.

The windowed peak detector circuit 88 is configured to reduce the target voltage bandwidth BW_{TGT} in the modulated digital target voltage V_{DTGT} to the limited bandwidth BW_{ETIC} of the ETIC 38.

FIGS. 6A and 6B are graphic diagrams providing exemplary illustrations of a window-based bandwidth adaptation scheme performed by the transceiver circuit 70 of FIG. 5. Elements in FIGS. 4 and 5 are referenced in conjunction with the description of FIGS. 6A and 6B and will not be re-described herein.

FIG. 6A illustrates the time-variant amplitude \sqrt{I²+Q²} as detected from the frequency-equalized modulation vector b_{MOD-E}^{→}. In an embodiment, the time-variant amplitude \sqrt{I²+Q} is divided into multiple sampling windows W₁-W_{N}. Notably, the sampling windows W₁-W_{N} are non-overlapping windows each including one or more amplitude samples 92 of the time-variant amplitude \sqrt{I²+Q²} defined by a grouping factor K (K=1, 2, or 4).

The grouping factor K is determined based on a relationship between the limited modulation bandwidth BW_{ETIC} of the ETIC 38 and the signal modulation bandwidth BW_{MOD} of the RF signal 48. When the signal modulation bandwidth BW_{MOD} is higher than the limited modulation bandwidth BW_{ETIC} (BW_{MOD}>BW_{ETIC}), the grouping factor K will be greater than one (1) (K>1). As such, each of the sampling windows W₁-W_{N} will include the multiple amplitude samples 94 of the time-variant amplitude \sqrt{I²+Q²}.

As an example, FIG. 6A illustrates modulation bandwidth adaptation performed by the voltage processing circuit 76 based on a grouping factor K=2, which means that each of the sampling windows W₁-W_{N} includes two amplitude samples 92 of the time-variant amplitude \sqrt{I²+Q²}. In a non-limiting example, the grouping factor K is set to equal 2 when the signal modulation bandwidth BW_{MOD} is approximately twice the limited modulation bandwidth BW_{ETIC} (BW_{MOD}≈2×BW_{ETIC}). In this regard, the windowed peak detector circuit 88 is configured to detect a peak amplitude 94 among the amplitude samples 92 of the equalized modulation vector b_{MOD-E}^{→} in each of the sampling windows W₁-W_{N}. Accordingly, as illustrated in FIG. 6B, the windowed peak detector circuit 88 can generate a sampled modulation vector b_{SMP}^{→} in the target voltage bandwidth BW_{TGT} based on the peak amplitude 94 detected in each of the sampling windows W₁-W_{N}.

In this example, since the grouping factor K is equal to 2, the target voltage bandwidth BW_{TGT} will be approximately equal to one-half (½) of the signal modulation bandwidth BW_{MOD}. More generally speaking, the target voltage bandwidth BW_{TGT} will be approximately equal to one-Kth of the signal modulation bandwidth BW_{MOD} (BW_{TGT}=BW_{MOD}/K). Notably, when K=1, the target voltage bandwidth BW_{TGT} will be equal to the signal modulation bandwidth BW_{MOD}. Thus, by properly determining the grouping factor K based on the defined bandwidth limit BW_{ETIC} and the signal modulation bandwidth BW_{MOD}, it is possible to prevent the ETIC 38 from being forced to limit the bandwidth of the modulated voltage V_{CC} to thereby prevent distortion in the modulated voltage V_{cc}.

With reference back to FIG. 5, the ET LUT circuit 90 may include a LUT (not shown) that correlates different levels of the peak amplitudes 94 detected in the sampling windows W₁-W_{N} with different levels of the modulated digital target voltage V_{DTGT}. Accordingly, the ET LUT circuit 90 can generate the modulated digital target voltage V_{DTGT} based on the detected peak amplitudes 94 in the sampled modulation vector b_{SMP}^{→}.

In an embodiment, the voltage processing circuit 76 may further include a window-based current processing circuit 96. The window-based current processing circuit 96 is configured to generate a windowed compensation term V_{TERM-WIN} based on the modulated digital target voltage V_{DTGT} and the total inductive impedance L_{TRACE-ETIC} presented at the differential power amplifier circuit 36. In contrast to the compensation term V_{TERM} generated by the current processing circuit 80, the windowed compensation term V_{TERM-WIN} is associated with the voltage modulation bandwidth BW_{VCC} to thereby cancel the ripple across the voltage modulation bandwidth BW_{VCC}. The voltage processing circuit 76 may then add the windowed compensation term V_{TERM-WIN} into the modulated digital target voltage V_{DTGT}.

In an embodiment, the signal processing circuit 72 includes a windowing buffer 98 and a modulator circuit 100. The windowing buffer 98 may be configured to temporally buffer an equal number of the amplitude samples of the time-variant modulation vector b_{MOD}^{→} as the amplitude samples 92 of the equalized modulation vector b_{MOD-E}^{→} in each of the sampling windows W₁-W_{N}.

In the example illustrated in FIGS. 6A and 6B, each of the sampling windows W₁-W_{N} includes two amplitude samples 92 of the equalized modulation vector b_{MOD-E}^{→}. In this regard, the windowing buffer 98 will buffer two amplitude samples of the time-variant modulation vector b_{MOD}^{→} as well. Accordingly, the windowing buffer 98 will generate a windowed modulation vector b_{WIN}^{→} that may be time synchronized with the sampled modulation vector b_{SMP}^{→}. Subsequently, the modulator circuit 100 can be configured to generate the RF signal 48 from the windowed modulation vector b_{WIN}^{→}.

The signal processing circuit 72 may further include a memory digital predistortion (mDPD) circuit 102. The mDPD circuit 102 can be configured to digitally pre-distort the windowed modulation vector b_{WIN}^{→} before the modulator circuit 100 generates the RF signal 48 from the windowed modulation vector b_{WIN}^{→}.

Herein, the current processing circuit 80 includes an equalizer circuit 104, an amplitude detector circuit 106, a load LUT circuit 108, and a filter circuit 110. The equalizer circuit 104 is configured to apply a complex current filter H_{ETRC}(s) to the time-variant modulation vector b_{MOD}^{→} to generate an equalized modulation vector b_{MOD-E1}^{→}. Herein, the complex current filter H_{ETRC}(s) may be determined to provide a different shape in frequency response within the modulation bandwidth of the wireless transmission circuit 68. In this regard, the complex current filter H_{ETRC}(s) can be different from the complex voltage filter H_{ET}(s).

The amplitude detector circuit 106 is configured to detect a time-variant amplitude \sqrt{I²+Q²} of the equalized modulation vector b_{MOD-E1}^{→}. The load LUT circuit 108 may include a current LUT (not shown) that is predetermined to correlate the time-variant input power P_{IN} (as represented by the detected time-variant amplitude \sqrt{I²+Q²} of the equalized modulation vector b_{MOD-E1}^{→}) with different digital current terms. Accordingly, the load LUT circuit 108 can generate a time-variant digital current term I_{TERM} based on the detected time-variant amplitude \sqrt{I²+Q²} of the equalized modulation vector b_{MOD-E1}^{→}. The current processing circuit 80 may include a scaler 112 to scale the detected time-variant amplitude \sqrt{I²+Q²} based on a scaling factor 114 before the load LUT circuit 108 generates the time-variant digital current term I_{TERM} from the detected time-variant amplitude \sqrt{I²+Q²}.

The filter circuit 110 is configured to convert the time-variant digital current term I_{TERM} into the compensation term V_{TERM}. In a non-limiting example, the filter circuit 110 can be configured to convert the time-variant digital current term I_{TERM} into the compensation term V_{TERM} based on a Z-transform function expressed in equation (Eq. 6).

$${V}_{TERM} = [ ( {L}_{ETIC} + {L}_{TRACE} ) / {T}_{S} ] * ( 1 - {z}^{- 1} ) \qquad ( Eq . 6 )$$

In the equation (Eq. 6), T_{S} represents a sampling clock period used in the digital domain, and z⁻¹ represents the Z transform. The combiner 82 is configured to combine the compensation term V_{TERM} with the modulated digital target voltage V_{DTGT} to create the modified digital target voltage V_{DTGT-MOD}.

In an embodiment, the current processing circuit 80 may include an adjustable delay circuit 116. The adjustable delay circuit 116 may be coupled between the load LUT circuit 108 and the filter circuit 110. The adjustable delay circuit 116 may be configured to introduce an adjustable delay term τ₁ into the time-variant digital current term I_{TERM}. The adjustable delay term τ₁ may be determined (e.g., via experiment) to cause the modulated current I_{CC} to be time aligned with the modulated voltage V_{CC} at the differential power amplifier circuit 36.

In addition, the voltage processing circuit 76 may include a second delay circuit 118 and the signal processing circuit 72 may include a third delay circuit 120. The second delay circuit 118 may be configured to introduce a second adjustable delay term τ₂ into the modulated digital target voltage V_{DTGT}. The third delay circuit 120 may be configured to introduce a third adjustable delay term τ₃ into the windowed modulation vector b_{WIN}^{→}. In this regard, the adjustable delay term τ₁, the second adjustable delay term τ₂, and/or the third adjustable delay term τ₃ may be adjusted to ensure proper alignment among the modulated voltage V_{CC}, the modulated current I_{CC}, and the time-variant input power P_{IN} at the differential power amplifier circuit 36.

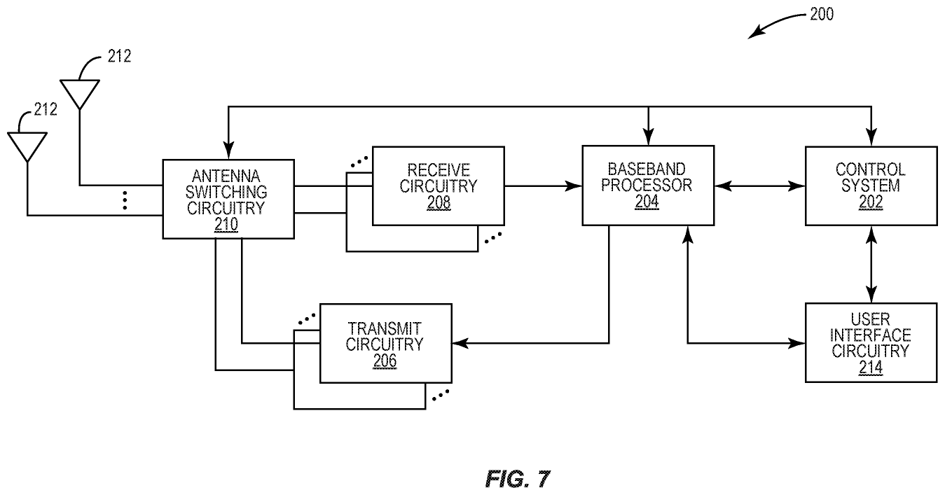

The wireless transmission circuit 68 of FIG. 4, which includes the differential power amplifier circuit 36 of FIG. 2 and the transceiver circuit 70 of FIG. 5, can be provided in a communication device to support the embodiments described above. In this regard, FIG. 7 is a schematic diagram of an exemplary communication device 200 wherein the wireless transmission circuit 68 of FIG. 4 can be provided.

Herein, the communication device 200 can be any type of communication device, such as mobile terminal, smart watch, tablet, computer, navigation device, access point, base station (e.g., eNB, gNB, etc.), and any other kind of wireless communication device that support wireless communications, such as cellular, wireless local area network (WLAN), Bluetooth, Ultra-wideband (UWB), and near field communications. The communication device 200 will generally include a control system 202, a baseband processor 204, transmit circuitry 206, receive circuitry 208, antenna switching circuitry 210, multiple antennas 212, and user interface circuitry 214. In a non-limiting example, the control system 202 can be a field-programmable gate array (FPGA), as an example. In this regard, the control system 202 can include at least a microprocessor(s), an embedded memory circuit(s), and a communication bus interface(s). The receive circuitry 208 receives radio frequency signals via the antennas 212 and through the antenna switching circuitry 210 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and application specific integrated circuits (ASICs).

For transmission, the baseband processor 204 receives digitized data, which may represent voice, data, or control information, from the control system 202, which it encodes for transmission. The encoded data is output to the transmit circuitry 206, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 212 through the antenna switching circuitry 210. The multiple antennas 212 and the replicated transmit and receive circuitries 206, 208 may provide spatial diversity. Modulation and processing details will be understood by those skilled in the art.

In an embodiment, the wireless transmission circuit 68 can be provided in the transmit circuitry 206. The frontend circuit 37, on the other hand, can be functionally equivalent to the antenna switching circuitry 210 or be part of the antenna switching circuitry 210.

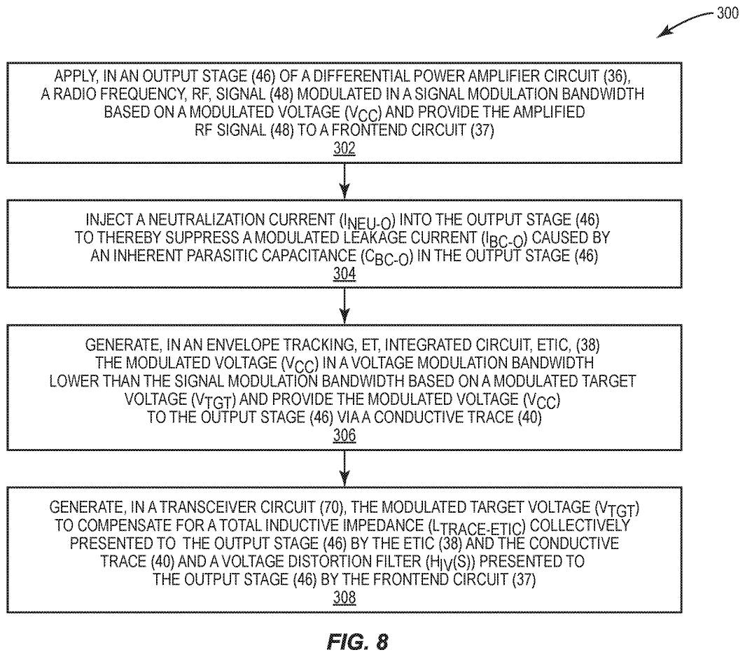

In an embodiment, the wireless transmission circuit 68 of FIG. 4 can be configured to suppress voltage ripple and neutralize memory distortion according to a process. In this regard, FIG. 8 is a flowchart of an exemplary process 300 for suppressing voltage ripple and neutralizing memory distortion in the wireless transmission circuit 68 of FIG. 4.

Herein, the process 300 includes applying, in the output stage 46 of the differential power amplifier circuit 36, the RF signal 48 modulated in the signal modulation bandwidth based on the modulated voltage V_{CC} and providing the amplified RF signal 48 to the frontend circuit 37 (step 302). The process 300 also includes injecting the neutralization current I_{NEU-O} into the output stage 46 to thereby suppress the modulated leakage current I_{BC-O} caused by the inherent parasitic capacitance C_{BC-O} in the output stage 46 (step 304). The process 300 also includes generating, in the ETIC 38 the modulated voltage V_{CC} in the voltage modulation bandwidth lower than the signal modulation bandwidth based on the modulated target voltage V_{TGT} and providing the modulated voltage V_{CC} to the output stage 46 via the conductive trace 40 (step 306). The process 300 also includes generating, in the transceiver circuit 70, the modulated target voltage V_{TGT} to compensate for the total inductive impedance L_{TRACE-ETIC} collectively presented to the output stage 46 by the ETIC 38 and the conductive trace 40 and the voltage distortion filter H_{IV}(s) presented to the output stage 46 by the frontend circuit 37 (step 308).

Those skilled in the art will recognize improvements and modifications to the preferred embodiments of the present disclosure. All such improvements and modifications are considered within the scope of the concepts disclosed herein and the claims that follow.

1. A wireless transmission circuit comprising:
a differential power amplifier circuit comprising:
an output stage configured to amplify a radio frequency RF) signal modulated in a signal modulation bandwidth based on a modulated voltage and provide the amplified RF signal to a frontend circuit; and
a neutralization circuit configured to inject a neutralization current into the output stage to thereby suppress a modulated leakage current caused by an inherent parasitic capacitance in the output stage;
an envelope tracking (ET) integrated circuit (ETIC) coupled to the output stage via a conductive trace and configured to generate the modulated voltage in a voltage modulation bandwidth lower than the signal modulation bandwidth based on a modulated target voltage; and
a transceiver circuit configured to:
generate the RF signal in the signal modulation bandwidth; and
generate the modulated target voltage configured to compensate for a total inductive impedance collectively presented to the output stage by the ETIC and the conductive trace and a voltage distortion filter presented to the output stage by the frontend circuit.

2. The wireless transmission circuit of claim 1, wherein the output stage comprises:
an interstage transformer configured to receive the RF signal;
a pair of differential amplifiers each configured to amplify the RF signal based on the modulated voltage and having the inherent parasitic capacitance that interacts with the modulated voltage to cause the modulated leakage current; and
an output transformer configured to output the amplified RF signal to the frontend circuit;
wherein the neutralization circuit is further configured to inject the neutralization current into each of the pair of differential amplifiers to thereby suppress the modulated leakage current in each of the pair of differential amplifiers.

3. The wireless transmission circuit of claim 2, wherein the neutralization circuit is coupled between a center tap of the interstage transformer and a center tap of the output transformer and configured to:
receive the modulated voltage via the center tap of the output transformer;
derive the neutralization current from the modulated voltage; and
inject the neutralization current into each of the pair of differential amplifiers via the center tap of the interstage transformer.

4. The wireless transmission circuit of claim 3, wherein the neutralization circuit comprises:
a heterojunction bipolar transistor (HBT) configured to derive the neutralization current from the modulated voltage; and
a mirroring circuit configured to amplify the neutralization current and inject the amplified neutralization current into the center tap of the interstage transformer.

5. The wireless transmission circuit of claim 1, wherein the neutralization circuit is further configured to generate the neutralization current at a baseband frequency.

6. The wireless transmission circuit of claim 1, wherein the transceiver circuit comprises:
a signal processing circuit configured to modulate the RF signal to the signal modulation bandwidth based on a time-variant modulation vector; and
a voltage processing circuit configured to cause the modulated target voltage to be generated in a target voltage bandwidth that is lower than or equal to a defined bandwidth limit of the ETIC when the signal modulation bandwidth is higher than the defined bandwidth limit of the ETIC.

7. The wireless transmission circuit of claim 6, wherein the voltage processing circuit comprises:
a frequency equalizer circuit configured to apply a complex filter to the time-variant modulation vector to generate a frequency-equalized modulation vector that can compensate for the voltage distortion filter;
an amplitude detector configured to detect a time-variant amplitude of the frequency-equalized modulation vector;
a windowed peak detector circuit configured to:
generate one or more amplitude samples of the frequency-equalized modulation vector in each of a plurality of sampling windows;
detect a peak amplitude among the one or more amplitude samples in each of the plurality of sampling windows; and
generate a sampled modulation vector in the target voltage bandwidth and comprising the peak amplitude detected in each of the plurality of sampling windows; and
an ET lookup table (LUT) circuit configured to generate a modulated digital target voltage based on the sampled modulation vector.

8. The wireless transmission circuit of claim 7, wherein the windowed peak detector circuit is further configured to:
generate one amplitude sample of the frequency-equalized modulation vector when the signal modulation bandwidth of the RF signal is lower than or equal to the defined bandwidth limit of the ETIC; and
generate multiple amplitude samples of the frequency-equalized modulation vector when the signal modulation bandwidth of the RF signal is higher than the defined bandwidth limit of the ETIC.

9. The wireless transmission circuit of claim 7, wherein the voltage processing circuit is further configured to:
generate a windowed compensation term based on the modulated digital target voltage and the total inductive impedance; and
add the windowed compensation term into the modulated digital target voltage.

10. The wireless transmission circuit of claim 9, wherein the transceiver circuit further comprises:
a current processing circuit configured to generate a compensation term based on the modulated voltage and the total inductive impedance;
a combiner configured to combine the compensation term and the modulated digital target voltage to generate a modified digital target voltage; and
a digital-to-analog converter (DAC) configured to convert the modified digital target voltage into the modulated target voltage.

11. A method for suppressing voltage ripple and neutralizing memory distortion in a wireless transmission circuit comprising:
amplifying, in an output stage of a differential power amplifier circuit, a radio frequency (RF) signal modulated in a signal modulation bandwidth based on a modulated voltage and providing the amplified RF signal to a frontend circuit;
injecting a neutralization current into the output stage to thereby suppress a modulated leakage current caused by an inherent parasitic capacitance in the output stage;
generating, in an envelope tracking (ET) integrated circuit (ETIC) the modulated voltage in a voltage modulation bandwidth lower than the signal modulation bandwidth based on a modulated target voltage and providing the modulated voltage to the output stage via a conductive trace; and
generating, in a transceiver circuit, the modulated target voltage to compensate for a total inductive impedance collectively presented to the output stage by the ETIC and the conductive trace and a voltage distortion filter presented to the output stage by the frontend circuit.

12. The method of claim 11, further comprising generating the neutralization current at a baseband frequency.

13. The method of claim 11, further comprising:
modulating the RF signal to the signal modulation bandwidth based on a time-variant modulation vector; and
generating the modulated target voltage to be generated in a target voltage bandwidth that is lower than or equal to a defined bandwidth limit of the ETIC when the signal modulation bandwidth is higher than the defined bandwidth limit of the ETIC.

14. The method of claim 13, further comprising:
applying a complex filter to the time-variant modulation vector to generate a frequency-equalized modulation vector that can compensate for the voltage distortion filter;
detecting a time-variant amplitude of the frequency-equalized modulation vector;
generating one or more amplitude samples of the frequency-equalized modulation vector in each of a plurality of sampling windows;
detecting a peak amplitude among one or more amplitude samples in each of the plurality of sampling windows;
generating a sampled modulation vector in the target voltage bandwidth and comprising the peak amplitude detected in each of the plurality of sampling windows; and
generating a modulated digital target voltage based on the sampled modulation vector.

15. The method of claim 14, further comprising:
generating one amplitude sample of the frequency-equalized modulation vector when the signal modulation bandwidth of the RF signal is lower than or equal to the defined bandwidth limit of the ETIC; and
generating multiple amplitude samples of the frequency-equalized modulation vector when the signal modulation bandwidth of the RF signal is higher than the defined bandwidth limit of the ETIC.

16. The method of claim 14, further comprising:
generating a windowed compensation term based on the modulated digital target voltage and the total inductive impedance; and
adding the windowed compensation term into the modulated digital target voltage.

17. The method of claim 16, further comprising:
generating a compensation term based on the modulated voltage and the total inductive impedance;
combining the compensation term and the modulated digital target voltage to generate a modified digital target voltage; and
converting the modified digital target voltage into the modulated target voltage.

18. A wireless device comprising:
a frontend circuit; and
a wireless transmission circuit comprising:
a differential power amplifier circuit comprising:
an output stage configured to amplify a radio frequency (RF signal modulated in a signal modulation bandwidth based on a modulated voltage and provide the amplified RF signal to the frontend circuit; and
a neutralization circuit configured to inject a neutralization current into the output stage to thereby suppress a modulated leakage current caused by an inherent parasitic capacitance in the output stage;
an envelope tracking (ET) integrated circuit (ETIC) coupled to the output stage via a conductive trace and configured to generate the modulated voltage in a voltage modulation bandwidth lower than the signal modulation bandwidth based on a modulated target voltage; and
a transceiver circuit configured to:
generate the RF signal in the signal modulation bandwidth; and
generate the modulated target voltage configured to compensate for a total inductive impedance collectively presented to the output stage by the ETIC and the conductive trace and a voltage distortion filter presented to the output stage by the frontend circuit.

19. The wireless device of claim 18, wherein the output stage comprises:
an interstage transformer configured to receive the RF signal;
a pair of differential amplifiers each configured to amplify the RF signal based on the modulated voltage and having the inherent parasitic capacitance that interacts with the modulated voltage to cause the modulated leakage current; and
an output transformer configured to output the amplified RF signal to the frontend circuit;
wherein the neutralization circuit is further configured to inject the neutralization current into each of the pair of differential amplifiers to thereby suppress the modulated leakage current in each of the pair of differential amplifiers.

20. The wireless device of claim 18, wherein the transceiver circuit comprises:
a signal processing circuit configured to modulate the RF signal to the signal modulation bandwidth based on a time-variant modulation vector; and
a voltage processing circuit configured to cause the modulated target voltage to be generated in a target voltage bandwidth that is lower than or equal to a defined bandwidth limit of the ETIC when the signal modulation bandwidth is higher than the defined bandwidth limit of the ETIC.
